(19) United States
(12) Patent Application Publication
(10) Pub. No.: US 2006/0221572 A1
(43) Pub. Date: Oct. 5, 2006

(54) Stud-nut

(76) Inventor: Richard Power-Fardy, Ottawa (CA)

Correspondence Address: ZITO TLP, 26005 RIDGE ROAD, SUITE 203, DAMASCUS, MD, 20872, US

(21) Appl. No.: 11/096,105

(22) Filed: Mar. 31, 2005

(51) Int. Cl. H05K 7/20

(52) U.S. Cl. 361/704

(57) ABSTRACT

A tubular stud-nut providing precise, adjustable physical separation between a first and second component. The stud-nut includes male threads on the external cylindrical surface and female threads on the internal surface of the axial bore. The stud-nut also includes a mechanical keying slot to facilitate turning of the stud-nut within a threaded mating hole located within the first component, thus enabling axial adjustment of the stud-nut by extension and retraction. With the stud-nut positioned in the mating hole of the first component, the two components are placed into relative position, Turning the stud-nut with respect to its mating hole, the stud-nut is adjusted to contact the surface of the second component. A locking fastener is threaded into the stud-nut through a concentric aperture in the second component, thereby locking said two components precisely in place. Alternatively, the stud-nut may be used to provide precision adjustment between said components.

### FIELD OF THE INVENTION

The present invention relates to mechanically fixing two or more components in set spacial arrangements. More specifically, this invention comprises a device and method for precisely positioning, adjusting and securely retaining assembled components at optimum separation distances relative to each other.

### BACKGROUND OF THE INVENTION

The process of manufacturing circuit card assemblies includes assembling the necessary electronic components onto a printed wiring board. Some electronic components require heat sinks to dissipate unwanted heat.

Usually, if the heat sink is in direct mechanical contact with the component, it may damage the electronics of the part due to mechanical contact between hard surfaces. Therefore, to safely transfer heat from the component to the heat sink, a thermal transferring material is often used. These materials are positioned between the component and the heat sink.

Thermal transferring materials come in many forms, for example, compressible pads, thermal set pastes, etc. They are generally poor conductors of heat compared to the heat sink materials. Heat will be drawn off the component more efficiently if the through-thickness of the thermal transferring material is kept to a minimum. Therefore, in order to most efficiently cool the component, it is desirable to utilize a very thin thermal transferring material layer. This requires precise and secure location of the heat sink very close to the component.

However, all electronic parts have variations in height from batch to batch. Therefore, in addition to the heat sink needing to be positioned closely and securely in precise tolerance to the component, it is desirable to be able to adjust the position of the heat sink relative to the component on successive batches.

There is a need then, for a heat sink-to-component adjustment mechanism providing precision spacial adjustment of the two parts, to achieve an optimum distance setting as required for the specific parts to be joined, and with secure fixing of said optimum distance setting between the two parts.

### SUMMARY OF THE INVENTION

An invention is disclosed comprising a combination stud and nut (a stud-nut) with features enabling the stud-nut to be utilized as both a component positioning stud bolt and a receiving nut for a position-locking, threaded fastener.

A tubular section is threaded on both its outside and inside surfaces. In an exemplary application of the invention, the outside threading of the stud-nut matches that of a mating stud hole located in the body of a first component, which is to be precisely and securely positioned relative to a second component. The inside surface thread is matched to that of a screw or other threaded fastener which is to be used to hold said second component in place in said position.

The stud-nut has two ends, both of which are flat and perpendicular to the axis of the stud-nut. At one end of the stud-nut there is a slot or alternate drive mechanism to facilitate the turning (threading) of the stud-nut into said mating hole.

In the exemplary application, the first component is a heat sink and the second component is a printed wiring board, upon which is mounted an electronic part and a thermal transferring material. The heat sink is to be positioned such that it rests against a very thin layer of thermal transferring material. The positioning must be very precise so as to allow efficient heat transfer with no damage to the electronic part. Such an application is shown in FIGS. 3 and 4.

The heat sink is placed into position against the thermal transferring material. Stud-nuts are positioned in the mating holes of the heat sink and threaded into the holes until the leading ends of the stud-nuts engage the surface of the printed wiring board. The heat sink and printed wiring board are both designed such that mating holes in the heat sink line up with concentric fastener holes in the printed circuit board.

Threaded fasteners, machine screws in this embodiment, are passed through the fastener holes and are threaded into the centers of the stud-nuts.

The threaded fasteners are tightened, securing the printed wiring board in place relative to the stud-nuts because the stud-nuts can no longer rotate. The heat sink will therefore also be locked into position relative to the stud-nuts, and likewise, to the printed wiring board.

In an alternative application, the stud-nuts may be preliminarily threaded into mating holes in a first component, which is then placed into position against a second component. The stud-nut may be threaded into or out of the holes in the first component, adjusting the position of the first component relative to the second component until the two components reach the desired spacing. Threaded fasteners are then passed through holes in the printed curcuit board and threaded into the stud-nuts, locking the two components together at the desired spacing.

Although the use of the invention has been depicted in very specific applications, these depictions are provided in an illustrative rather than a limiting sense. Any application of the stud-nut making use of its precise positioning, adjusting and position-locking capabilities may be employed without departing from the teachings of the invention.

### BRIEF DESCRIPTION OF THE DRAWINGS

Exemplary embodiments of the invention are discussed hereinafter in reference to the following drawings, in which:

FIG. 1 is a section view of the stud-nut depicting its threaded external surface, its threaded internal surface and an embodiment of a turning groove.

FIG. 2 is a perspective view of the stud-nut, providing a better view of the exemplary drive slot.

FIG. 3 is a view of the stud-nut in a heat sink positioning application.

FIG. 4 is a perspective view of the positioning application of FIG. 3.

### DETAILED DESCRIPTION OF PREFERRED EXEMPLARY EMBODIMENTS

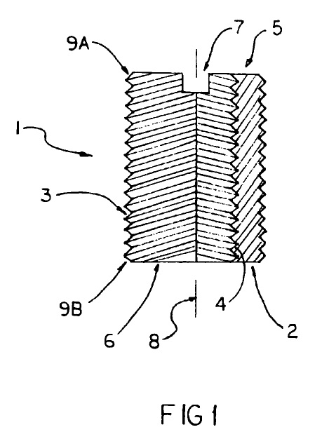

As is illustrated in FIG. 1, the present invention comprises a combination stud bolt and locking fastener nut (stud-nut) 1 with features enabling said invention to be utilized as both a component positioning stud and a position-locking, fastener-receiving nut in a two-component positioning, position adjustment and position locking application.

Said stud-nut 1 comprises a tubular section 2 with a threaded external surface 3, a threaded internal bore 4, a first end 5, a second end 6, and a drive slot 7 in said first end 5. Section 2 may be made of metal or any reasonably stiff, durable material.

External surface 3 and internal bore 4 are concentric with respect to axis 8. Said cylindrical surfaces may be configured to any diameters as appropriate for any dimensional and structural requirements of an application of said stud-nut, and the threading on said surfaces may be done in accordance with any specification suitable to such application, an exemplary embodiment of which is described hereunder.

First end 5 and second end 6 are flat surfaces, configured perpendicular to axis 8. Second end 6 will be smooth, the degree of said smoothness being suited to any specific application, an exemplary embodiment of which is described hereunder. The edges (9A and 9B respectively) of said first and second ends may be contoured as required to suit any application.

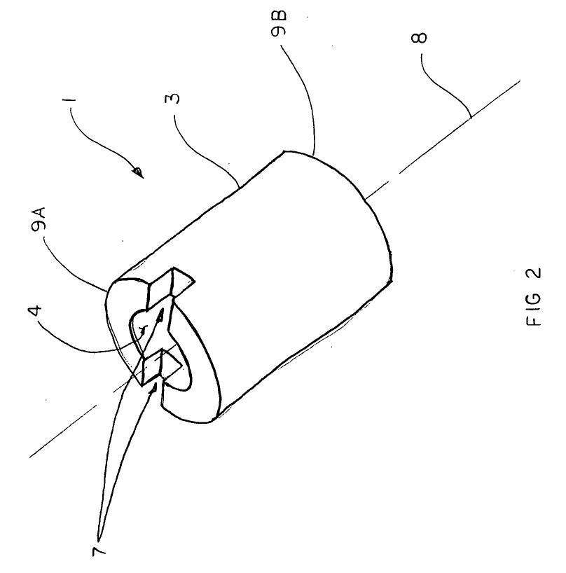

Slot 7 diametrically transverses end 5, as is better illustrated in FIG. 2. The purpose of said slot is to facilitate turning of and/or prevention of rotation of stud-nut 1 by a mechanical key (such as a common screwdriver) within any threaded hole into which said stud-nut is placed. While stud-nut 1 is illustrated with slot 7 as the exemplary turning mechanism, any type of turning mechanism may be used without departing from the teachings of the invention.

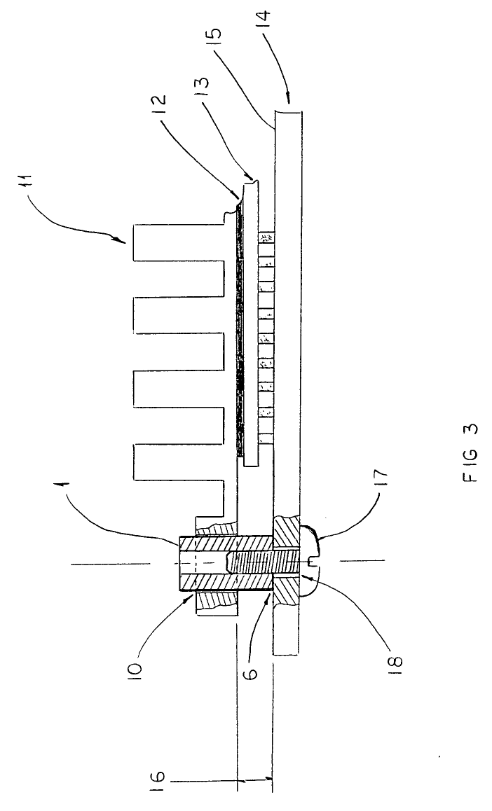

FIG. 3 indicates an exemplary application of stud-nut 1. Said application consists of inserting said stud-nut into a stud hole 10 in the body of a heat sink 11. Said heat sink is placed against thermal transferring layer 12 which bonds said heat sink to an electronic part 13 which is installed on a printed wiring board 14.

Stud-nut 1 is threaded into stud hole 10 until second end surface 6 comes to rest firmly on top surface 15 of printed wiring board 14. Precision adjustment of the distance 16 from said heat sink to top surface 15, if required, may be accomplished by turning said stud-nut within stud hole 10.

With heat sink 11 positioned as required relative to top surface 15, a fastener 17 is inserted through fastener hole 18 in printed wiring board 14 and is threaded into stud-nut 1. In this exemplary application, fastener hole 18 has been designed to be located concentric with stud hole 10 and the threading of internal bore 4 has been chosen to match that of fastener 17. Fastener 17 is depicted as a threaded machine screw. However, any other type of threaded fastener may be utilized without departing from the teachings of the present invention.

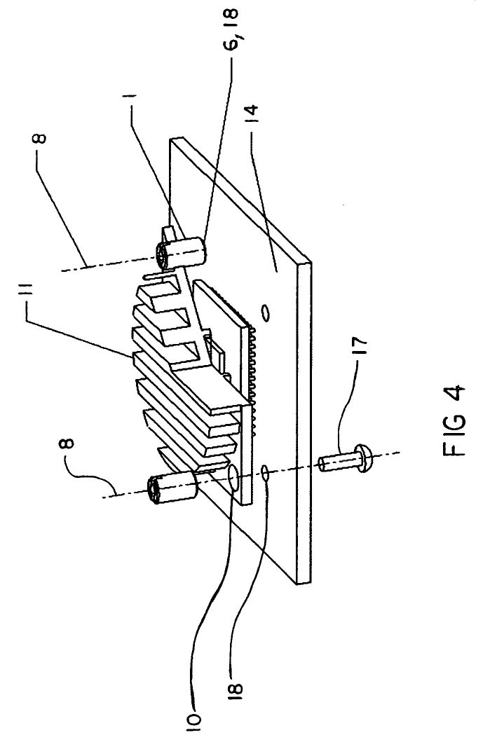

Fastener 17 is tightened against printed wiring board 14, locking the position of stud-nut 1 relative to said printed wiring board. Presuming at least one other similar application of a stud-nut within heat sink 11, as is illustrated in FIG. 4, stud-nut 1 is now also locked into position relative to said heat sink. This secures the position of heat sink 11 relative to that of printed wiring board 14 at distance 16.

The exemplary embodiment discloses a stud-nut employed in a heat sink positioning application, providing adjustment and locking of said heat sink into a desired position relative to a printed wiring board. However, the stud-nut may be employed in any other application without departing from the scope of the present invention.

Because many varying and different embodiments may be made within the scope of the inventive concept herein taught, and because many modifications may be made in the embodiments herein detailed in accordance with the descriptive requirements of the law, it is to be understood that the details herein are to be interpreted as illustrative and not in a limiting sense.

What is claimed is:

1. A stud-nut comprising:
a tubular section having:
a first end;
a second end;
a longitudinal axis, extending from said first end to said second end;
a cylindrical, threaded external surface, concentric with said longitudinal axis, of suitable configuration to engage a threaded stud hole in a first component;
a cylindrical threaded internal bore concentric with said longitudinal axis and of suitable configuration to engage a fastener projecting through a fastener hole in a second component and into said internal bore; and
a turning facilitation feature associated with said first end for rotating said stud-nut about said longitudinal axis.

2. The stud-nut of claim 1 wherein said second end comprises a flat surface.

3. The stud-nut of claim 2 wherein said flat surface is perpendicular to said longitudinal axis and lacks irregular surface defects as required for an intended application of said device, such as stable, accurate positioning.

4. The stud-nut of claim 1 wherein said turning facilitation feature comprises one or more mechanical keying slots extending across said first end.

5. A method of positioning a first component having at least one stud hole in relation to a second component having at least one respective fastener hole utilizing in combination, at least one stud-nut and one fastener, said stud-nut comprising:
a tubular section having:
a first end;
a second end;
a longitudinal axis, extending from said first end to said second end;
a cylindrical, threaded external surface, concentric with said longitudinal axis, of suitable configuration to engage a threaded stud hole in a first component;
a cylindrical threaded internal bore concentric with said longitudinal axis and of suitable configuration to engage a fastener projecting through a fastener hole in a second component and into said internal bore;
a turning facilitation feature associated with said first end for rotating said stud-nut about said longitudinal axis; and,
said fastener comprising:
a threaded post configured to engage by threading said threaded internal bore; and
a head configured to be larger than said fastener hole and having a rotation facilitation feature;
said method comprising the steps of:
placing said first component into a suitable precise position relative to said second component with at least one said stud hole concentric with said respective fastener hole in said second component;
threading said stud-nut into said stud hole in said first component by inserting said stud-nut into said stud-nut hole and turning said stud-nut about said longitudinal axis until said stud-nut engages said second component; and
inserting said fastener through said respective fastener hole in said second component and threading said fastener into said threaded internal bore of said stud-nut by inserting said fastener into said threaded internal bore of said stud-nut and rotating said fastener about said longitudinal axis of said stud-nut without allowing rotation of said stud-nut about said longitudinal axis until said head of said fastener engages said second component as required to maintain and secure said suitable position of said first component relative to said second component.

6. The method of claim 5 wherein said second end comprises a flat surface.

7. The method of claim 6 wherein said flat surface is perpendicular to said longitudinal axis and lacks irregular surface defects as required for an intended application of said device, such as stable, accurate positioning.

8. The method of claim 5 wherein said turning facilitation feature comprises one or more mechanical keying slots extending across said first end of said stud-nut.

9. The method of claim 5 wherein said rotation facilitation feature comprises one or more mechanical keying slots extending across said head of said fastener.

10. A method of positioning and adjusting said positioning of a first component having at least one stud hole in relation to a second component having at least one respective fastener hole utilizing in combination, at least one stud-nut and one fastener, said stud-nut comprising:
a tubular section with the features of:
a first end;
a second end;
a longitudinal axis, extending from said first end to said second end;
a cylindrical, threaded external surface, concentric with said longitudinal axis, of suitable configuration to engage a threaded stud hole in a first component;
a cylindrical threaded internal bore concentric with said longitudinal axis and of suitable configuration to engage a fastener projecting through a fastener hole in a second component and into said internal bore;
a turning facilitation feature associated with said first end for rotating said stud-nut about said longitudinal axis; and,
said fastener comprising:
a threaded post configured to engage by threading said threaded internal bore; and
a head configured to be larger than said fastener hole and having a rotation facilitation feature;
said method comprising the steps of:
placing said first component into a suitable approximate position relative to said second component with at least one said stud hole concentric with said respective fastener hole in said second component;
threading said stud-nut into said stud hole in said first component by inserting said stud-nut into said stud-nut hole and turning said stud-nut about said longitudinal axis until said stud-nut engages said second component;
inserting said fastener through said respective fastener hole in said second component and threading said fastener into said threaded internal bore of said stud-nut by inserting said fastener into said threaded internal bore of said stud-nut and rotating said fastener about said longitudinal axis of said stud-nut without allowing rotation of said stud-nut about said longitudinal axis until said head of said fastener engages said second component as required to permit rotation of said stud-nut within said stud hole;
adjusting said position of said first component relative to said second component by threading said stud-nut into or out of said stud hole by turning said stud-nut about said longitudinal axis and while counter rotating said fastener about said longitudinal axis of said stud-nut until said first component is positioned precisely relative to said second component; and
rotating said fastener about said longitudinal axis of said stud-nut without allowing rotation of said stud-nut about said longitudinal axis until said head of said fastener engages said second component as required to maintain and secure said suitable position of said first component relative to said second component.

11. The method of claim 10 wherein said second end comprises a flat surface.

12. The method of claim 11 wherein said flat surface is perpendicular to said longitudinal axis and lacks irregular surface defects as required for an intended application of said device, such as stable, accurate positioning.

13. The method of claim 10 wherein said turning facilitation feature comprises one or more mechanical keying slots extending across said first end of said stud-nut.

14. The method of claim 10 wherein said rotation facilitation feature comprises one or more mechanical keying slots extending across said head of said fastener.

15. The method of claim 5 wherein said turning step comprises:
inserting a turning device into said turning facilitation feature; and
rotating said turning device so as to effect rotation of said stud-nut.

16. The method of claim 5 wherein said rotating step comprises:
inserting a turning device into said rotation facilitation feature; and
rotating said turning device so as to effect rotation of said fastener.

17. The method of claim 10 wherein said turning step comprises:
inserting a turning device into said turning facilitation feature; and
rotating said turning device so as to effect rotation of said stud-nut.

18. The method of claim 10 wherein said rotating step comprises:
inserting a turning device into said rotation facilitation feature; and
rotating said turning device so as to effect rotation of said fastener.

19. The method of claim 15 wherein said turning device comprises one of a flat head, phillips head and square drive screwdriver, and an allen key.

20. The method of claim 16 wherein said turning device comprises one of a flat head, phillips head and square drive screwdriver, and an allen key.

21. The method of claim 17 wherein said turning device comprises one of a flat head or phillips head screwdriver.

22. The method of claim 18 wherein said turning device comprises one of a flat head or phillips head screwdriver.

23. The stud-nut of claim 1 wherein said fastener comprises a machine bolt.

24. The method of claim 5 wherein said fastener comprises a machine bolt.

25. The method of claim 10 wherein said fastener comprises a machine bolt.

26. A one-piece threaded metallic fastener comprising:
a body having substantially cylindrical shape with a first end, a second end, and a central bore therethrough along its longitudinal axis;
the surface of said central bore including female threads extending the length of said bore;
the external surface of said threaded fastener including male threads extending the length of said threaded fastener; and
at least one slot, extending substantially radially throughout said first end of said threaded fastener.
